(19) United States
(12) Patent Application Publication
(10) Pub. No.: US 2024/0105594 A1
(43) Pub. Date: Mar. 28, 2024

(54) ANTI-FUSE ELEMENT AND LIGHT-EMITTING DEVICE

(71) Applicant: NICHIA CORPORATION, Anan-shi (JP)

(72) Inventor: Hisashi KASAI, Tokushima-shi (JP)

(21) Appl. No.: 18/476,152

(22) Filed: Sep. 27, 2023

(30) Foreign Application Priority Data
Sep. 28, 2022 (JP) 2022-154688
May 30, 2023 (JP) 2023-089120

(51) Int. Cl. H01L 23/525; H01L 23/532; H01L 23/62

(52) U.S. Cl. CPC H01L 23/5254; H01L 23/5329; H01L 23/62

(57) ABSTRACT

An anti-fuse element includes a first electrode, an insulating layer disposed on the first electrode, and a second electrode disposed on the insulating layer. The insulating layer includes a first region and a second region, with a thickness of the first region being smaller than a thickness of the second region. An outer edge of the second electrode is located inward of an outer edge of the insulating layer in a top view.

### CROSS-REFERENCE TO RELATED APPLICATION

This application claims priority to Japanese Patent Application No. 2022-154688 filed on Sep. 28, 2022, and Japanese Patent Application No. 2023-089120 filed on May 30, 2023, the disclosures of which are hereby incorporated herein by reference in their entireties.

### TECHNICAL FILED

The present disclosure relates to an anti-fuse element and a light-emitting device.

### BACKGROUND

A light-emitting device including a light-emitting element through which a large current flows and a plurality of light-emitting elements connected in series or in parallel has recently been used. A light-emitting device in which an anti-fuse element serving as a new current-carrying path by dielectric breakdown of the anti-fuse element itself when, for example, a light-emitting element or the like cannot carry any current is provided together with the light-emitting element is being developed (see PCT Publication No. WO 2015/060278).

### SUMMARY

However, a uniform thickness of an insulating layer in the anti-fuse element may cause the dielectric breakdown at an undesirable position. When, in particular, power is supplied to the anti-fuse element by a current supply member such as a wire, a current concentrates in a dielectric breakdown portion of the anti-fuse element, a temperature around the dielectric breakdown portion increases, and thus the current supply member may melt.

An anti-fuse element disclosed in the present application includes a first electrode, an insulating layer disposed on the first electrode, and a second electrode disposed on the insulating layer. The insulating layer includes a first region and a second region, with a thickness of the first region being smaller than a thickness of the second region. An outer edge of the second electrode is located inward of an outer edge of the insulating layer in a top view.

A light-emitting device disclosed in the present application includes the anti-fuse element and a light-emitting element.

The present disclosure can provide an anti-fuse element that can generate a current-carrying path at a desired position when the anti-fuse element is subjected to dielectric breakdown and a light-emitting device using the anti-fuse element.

### BRIEF DESCRIPTION OF DRAWINGS

FIG. 1A is a top view of an anti-fuse element of a first embodiment.

FIG. 1B is a cross-sectional view thereof taken along line Ib-Ib in FIG. 1A.

FIG. 1C is a bottom view of the anti-fuse element.

FIG. 2A is a view for explaining a connection form in the anti-fuse element of FIG. 1.

FIG. 2B is a view for explaining another connection form in the anti-fuse element of FIG. 1.

FIG. 3A is a top view of a light-emitting device of a second embodiment.

FIG. 3B is a top view of the light-emitting device of FIG. 3A from which a cover is removed.

FIG. 3C is a cross-sectional view taken along line IIIc-IIIc in FIG. 3A.

FIG. 3D is a partial top view for explaining a positional relationship between a semiconductor laser element and the anti-fuse element in the light-emitting device of FIG. 3B.

FIG. 3E is a perspective view of the light-emitting device of FIG. 3A on which an optical member is disposed.

FIG. 4 is a circuit diagram of the light-emitting device of FIG. 3A.

### DETAILED DESCRIPTIONS

In the present description and the claims, a polygon, such as a triangle or a quadrangle, including a shape subjected to processing such as corner rounding, chamfering, corner cutting, or round cutting on a corner of the polygon and a shape subjected to processing on an intermediate portion of a side, is referred to as a polygon. The same applies to not only the polygon but also terms representing a specific shape such as a rectangle, a trapezoid, a circle, and unevenness.

In the present description or the claims, when a plurality of components corresponding to a certain component are distinguished from each other, the components may be denoted by “first,” “second,” and the like.

Embodiments of the present disclosure will be described below with reference to the drawings. However, the illustrated embodiments embody the technical concept of the present disclosure but do not limit the present disclosure. In the descriptions below, the same term or reference numeral represents the same member or a similar member, and duplicate descriptions will be omitted as appropriate. Sizes, positional relationships, and the like of members illustrated in the drawings may be exaggerated to facilitate understanding.

In the following description, a side on which a second electrode is disposed may be referred to as “upper”, a side on which a first electrode is disposed may be referred to as “lower”, and a top view refers to a view from a second electrode side.

### First Embodiment: Anti-Fuse Element

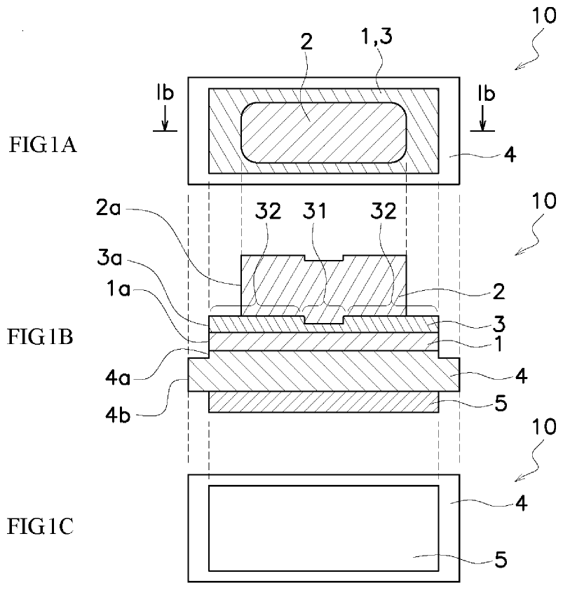

As illustrated in FIG. 1B, an anti-fuse element 10 of the first embodiment includes a first electrode 1, an insulating layer 3 disposed on the first electrode 1, and a second electrode 2 disposed on the insulating layer 3. The insulating layer 3 includes a first region 31 and a second region 32. A thickness of the first region 31 is smaller than a thickness of the second region 32. This configuration can achieve the anti-fuse element 10 that can generate a current-carrying path at a desired location when the anti-fuse element 10 is subjected to dielectric breakdown.

The thicker the insulating layer 3 is, the higher a voltage at which the dielectric breakdown occurs. Thus, providing the first region having a small thickness in the insulating layer and using this region as the current-carrying portion can control the current-carrying portion to a predetermined position set in advance. As a result, even when the current concentrates in the dielectric breakdown portion to increase the temperature around the breakdown portion, for example, setting the current-carrying portion away from the current supply member 41 can effectively suppress melting or damage of the current supply member 41 due to heat in the vicinity of the current supply member 41.

### First Electrode and Second Electrode

The first electrode 1 and the second electrode 2 are disposed with the insulating layer 3 interposed therebetween. As illustrated in, for example, FIG. 1B, the first electrode 1 can be disposed on the substrate 4, the insulating layer 3 can be disposed on the first electrode 1, and the second electrode 2 can be disposed on the insulating layer 3. In this case, the second electrode 2 is preferably exposed to the outside. Here, “exposed to the outside” means that a portion that is not in contact with the insulating layer 3 or a current supply member 41 described below is not covered with any of the insulating layer, a protective film, a semiconductor layer, a conductive layer, and the like and is exposed to the surrounding atmosphere. In particular, all of the portions that are not in contact with the insulating layer 3 or the current supply member 41 described below are preferably not covered with any of the insulating layer, the protective film, the semiconductor layer, the conductive layer, and the like. This facilitates handling in providing the current supply member 41 described below on the second electrode 2. Examples of the planar shapes of the first electrode 1 and the second electrode 2 include various shapes such as a circle or an ellipse, a polygon such as a triangle, a quadrangle, a hexagon, and an octagon or a shape with the corners of these shapes chamfered, and a shape with these shapes combined. In particular, as a result of the corners of the quadrangle being chamfered, the shape may become an octagon in a strict sense, but such a shape may also be referred to as a quadrangle with chamfered corners. The first electrode 1 and the second electrode 2 may have the same planar shape. In FIG. 1A, the first electrode 1 has a quadrangle, and the second electrode 2 has a quadrangle with chamfered corners. Here, the chamfering includes C-chamfering by which a corner is obliquely cut and R-chamfering by which a corner is rounded. When the second electrode 2 has a chamfered shape, the degree of chamfering can be appropriately set according to a size of the second electrode 2. When, for example, having the following sizes, the second electrode 2 has a range from R5 to R80 and preferably has a range from R10 to R60. Here, the unit of R is m. The second electrode 2 having a chamfered shape can locally mitigate the intensity of the electric field applied to the vicinity of the vertex of the quadrangle of the second electrode 2 as compared with the second electrode 2 having no chamfered shape.

The area of the first electrode 1 and the area of the second electrode 2 may be the same or different in a top view. In FIG. 1A, the second electrode 2 has a smaller area than the area of the first electrode 1. The hatching in FIG. 1A is for easily distinguishing between the first electrode 1 and the second electrode 2 and does not represent a cross-sectional view. Part or the whole of an outer edge 2a of the second electrode 2 is preferably located inward of an outer edge 1a of the first electrode 1 in a top view. In particular, in FIG. 1A, the whole outer edge 2a of the second electrode 2 is located inward of the outer edge 1a of the first electrode 1. Such a configuration can suppress a short circuit between the first electrode 1 and the second electrode 2 at the outer edge of the insulating layer 3. In this case, the plane area of the first electrode 1 is, for example, in a range from 105% to 200%, preferably in a range from 110% to 180%, and more preferably in a range from 120% to 170% of the plane area of the second electrode 2. Specifically, the first electrode 1 has a size of 350 μm×1000 μm or a size equivalent thereto or less, preferably has a size of 280 μm×900 μm or a size equivalent thereto or less, and more preferably has a size of 270 μm×520 μm or a size equivalent thereto or less. Such a size can allow the size of the whole anti-fuse element 10 to be small. Further, the first electrode 1 has a size of 190 μm×350 μm or a size equivalent thereto or more, preferably has a size of 200 μm×360 μm or a size equivalent thereto or more, and more preferably has a size of 240 μm×400 μm or a size equivalent thereto or more. Such a size can suppress the excessive current density flowing through the anti-fuse element 10.

The second electrode 2 has a size of 280 μm×900 μm or a size equivalent thereto or less, preferably has a size of 250 μm×500 μm or a size equivalent thereto or less, and more preferably has a size of 200 μm×450 μm or a size equivalent thereto or less. Such a size can allow the size of the whole anti-fuse element 10 to be small. Further, the second electrode 2 has a size of 120 μm×280 μm or a size equivalent thereto or more, preferably has a size of 130 μm×290 μm or a size equivalent thereto or more, and more preferably has a size of 170 μm×330 μm or a size equivalent thereto or more. Such a size can allow a space for disposing a current supply member 41 described below to be secured. In particular, when a plurality of the current supply members 41 is disposed, a distance between the current supply members 41 can be increased. In addition, a space for connecting the current supply members 41 at a plurality of positions can be readily ensured as described below.

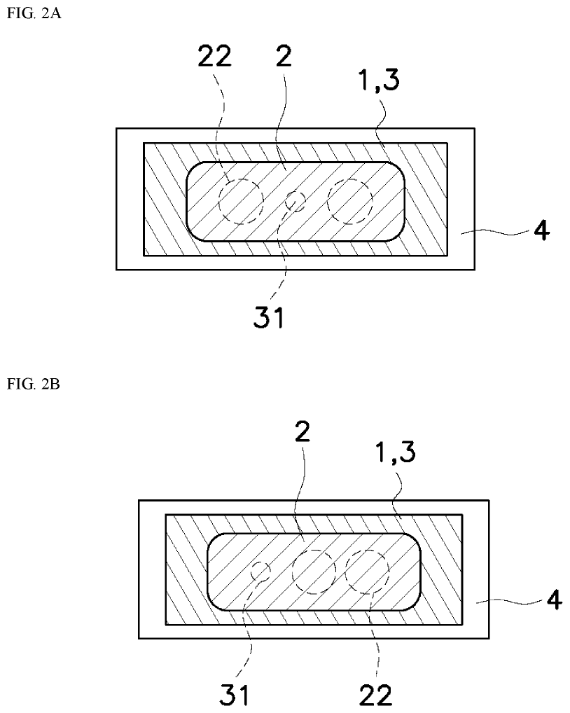

The thickness of each of the first electrode 1 and the second electrode 2 may be the same over the whole surface or may be partially different, or the surfaces thereof may partially have protrusions and/or depressions. Such a thickness and surface figure can be appropriately set depending on the applied voltage or the like. In particular, the first electrode 1 preferably has a uniform thickness and a flat upper surface in a cross-sectional view. The first electrode 1 has a thickness, for example, in a range from 0.1 μm to 10 μm, and preferably in a range from 0.1 μm to 1 μm. Such a thickness can allow the conductor resistance of the first electrode 1 to be low, and the electric conduction between the first electrode 1 and the second electrode 2 after the insulating layer 3 is subjected to dielectric breakdown. In a cross-sectional view, the second electrode 2 preferably has a uniform thickness on the second region 32 of the insulating layer 3 described below, more preferably has a flat upper surface, and still more preferably has the same thickness over the whole surface. Here, the uniform thickness means that the thicknesses of the first electrode 1 and the second electrode 2 are within a range of ±10% from a desired value. This can suppress the local concentration of the electric field intensity. The second electrode 2 preferably has a recess in the first region 31 of the insulating layer 3 described below. This makes the position of the first region 31 visible from above the anti-fuse element. The second electrode 2 has a thickness, for example, in a range from 1 μm to 20 μm, and preferably in a range from 2 μm to 8 μm. With this thickness, the second electrode can be suppressed from resistance increase. Also, when the plurality of current supply members 41 are connected to the second electrode 2 at the plurality of portions, such a thickness can readily distribute the current flow to the plurality of current supply members 41. Further, as illustrated in FIGS. 2A and 2B, a bonding region 22 is easily set to avoid the first region 31 from above when the current supply member is connected to the second electrode 2. The hatching in FIGS. 2A and 2B is for easily distinguishing between the first electrode 1 and the second electrode 2 and does not represent a cross-sectional view.

The first electrode 1 can have a single-layer structure or a multilayer structure containing, for example, a metal such as Au, Pt, Pd, Rh, Ru, Ir, Ni, W, Mo, Cr, V, Ti, Zr, Hf, Al, Cu, Ta, or Si or an alloy thereof. Specifically, the first electrode 1 can have a multilayer structure such as Rh/Pt/Au, Ni/Pt/Au, Ti/Ru/Ti, Ti/Al-Si/Ta/Ru, Rh/Ni/Au, Pt/Au/Ti, Pt/Au/Cr, Pt/Au/V, Pt/Au/Ni, Pt/Au/Zr, or Pt/Au/Hf. In the case of a multilayer structure, the metal disposed on the insulating layer 3 side is preferably a metal having good adhesion to the insulating layer 3, and is preferably Ti, V, Cr, Ni, Zr, or Hf, for example. In particular, the first electrode 1 preferably has a layered structure of Pt/Au/Ti in which Pt is on the substrate 4 side and Ti is on the insulating layer 3 side. Such a configuration can improve the adhesion between the first electrode 1 and the insulating layer 3.

The second electrode 2 can have a single-layer structure or a multilayer structure containing, for example, a metal such as Au, Pt, Pd, Rh, Ru, Ir, Ni, W, Mo, Cr, V, Ti, Zr, Hf, Al, Cu, Ta, or Si, or an alloy thereof. Specifically, the second electrode 2 can have a multilayer structure such as Ti/Rh/Au, Ti/Pt/Au, W/Pt/Au, Rh/Pt/Au, Ni/Pt/Au, Ti/Ru/Ti, Ti/Al-Si/Ta/Ru, Rh/Ni/Au, or Ru/Ni/Au. In the case of a multilayer structure, the metal disposed on the insulating layer 3 side is preferably a metal having good adhesion to the insulating layer 3, and is preferably Ti, V, Cr, Ni, Zr, or Hf, for example. In addition, when the current supply member 41 is provided on the upper surface of the second electrode 2, a metal having a good bonding property with the current supply member 41, for example, Au is preferably provided on the current supply member 41 side. Further, the metal disposed in the intermediate portion is preferably Pt, Ru, Rh, or Ir. In particular, the second electrode 2 preferably has a multilayer structure such as Ti/Pu/Au in which Ti is on the insulating layer 3 side and Au is on the upper surface side. Such a configuration can improve the adhesion between the second electrode 2 and the insulating layer 3 and improve the adhesion between the second electrode 2 and the current supply member 41.

The current supply member 41 is preferably connected to the upper surface of the second electrode 2. Specifically, the plurality of current supply members 41 are preferably connected to the second electrode 2 at the plurality of positions. When the plurality of current supply members 41 are provided, current cutoff due to the melting of the current supply members 41 or other factors can be suppressed with a high probability. Examples of the current supply member 41 include a string shaped wire and the like. The current supply member 41 may be formed of a metal such as Au. The bonding region 22 to which the current supply member 41 is connected is preferably located only at a portion of the second electrode 2 above the second region 32 of the insulating layer 3 as illustrated in FIGS. 2A and 2B. In other words, the bonding region 22 for the current supply member 41 is preferably not disposed above the first region 31 of the insulating layer 3, as described below. When the anti-fuse element 10 is subjected to dielectric breakdown, a current and heat concentrate in the first region 31 of the insulating layer 3, and the second region 32 of the insulating layer 3 has a relatively low temperature. Thus, providing the current supply member 41 only above the second region 32 of the insulating layer 3 can suppress melting or the like of the current supply member due to heat.

The substrate 4 on which the first electrode 1 or the second electrode 2 is disposed may be any of an insulating substrate, a semiconductor substrate, a conductive substrate, and the like, but is preferably a conductive substrate. The conductive substrate allows the substrate 4 to be used as a wiring path. In addition, the substrate 4 preferably has a high heat dissipation property. Having the high heat dissipation property suppresses the temperature of the anti-fuse element 10 from becoming high and easily controls the breakdown voltage and/or the breakdown position of the anti-fuse element 10. More preferably, the first electrode 1 is disposed on the conductive substrate. The conductive substrate can have a single-layer structure or a multilayer structure containing, for example, a metal such as Au, Pt, Pd, Rh, Ru, Ni, W, Mo, Cr, Ti, Al, Cu, Ta, or Si, or an alloy thereof. Further, the conductive substrate may have a single-layer structure or a multilayer structure including a semiconductor such as silicon or SiC.

The thickness of the substrate 4 can be appropriately set depending on the material used and the thicknesses of the first electrode 1, the second electrode 2, and the like. For example, the thickness is in a range from 50 μm to 150 μm. The substrate 4 may have protrusions and/or recessions on a lateral surface adjacent to the upper surface on which the first electrode 1 is disposed. In FIG. 1, the substrate 4 has a first edge portion 4a on the upper surface side and a second edge portion 4b on the lower surface side. The first edge portion 4a is located inward of the second edge portion 4b in a top view. Such a configuration can suppress the adhesive or the like from reaching the first edge portion 4a even when the adhesive or the like surrounds the substrate 4. In addition, the substrate 4 can include, in a thickness direction, the first edge portion 4a which coincides with (flush with) the outer edge 1a of the first electrode 1, and the second edge portion 4b located outward of the outer edge 1a of the first electrode 1. However, on the upper surface side of the substrate 4, the second edge portion 4b may coincide with the outer edge 1a of the first electrode 1, may be located inward of or outward of the outer edge 1a. In addition, as illustrated in FIG. 1B, the substrate 4 may have one step or two or more steps on the lateral surface in the cross section.

In FIG. 1B, the first electrode 1 is disposed on the substrate 4, and the first electrode 1 is smaller than the substrate 4. The second edge portion 4b on the upper surface side of the substrate 4 is located outward of the outer edge 1a of the first electrode 1 in a top view. In this case, the area of the region surrounded by the second edge portion 4b in a top view is, for example, in a range from 100% to 200%, preferably in a range from 110% to 180%, and more preferably in a range from 120% to 170% of the plane area of the first electrode 1. The size of the substrate 4 in a top view (the size of the second edge portion 4b) can be discretionarily set. For example, the size may be 400 μm×1050 μm or a size equivalent thereto or less, preferably 330 μm×950 μm or a size equivalent thereto or less, and more preferably 320 μm×570 μm or a size equivalent thereto or less. The size of the substrate 4 in a top view is, for example, 230 μm×390 m or a size equivalent thereto or more, preferably 240 μm×400 μm or a size equivalent thereto or more, and more preferably 280 μm×540 μm or a size equivalent thereto or more. Such a size can improve the handling property of the anti-fuse element 10.

The substrate 4 preferably has a back surface electrode 5 disposed on a surface opposite to the surface on which the insulating layer 3 is disposed. Such a configuration enables surface mounting of the anti-fuse element 10 on a submount 33, a bottom portion 39, or the like described below. The surface mounting can improve the heat dissipation property of the anti-fuse element 10 and stabilize the operating voltage of the anti-fuse element 10.

### Insulating Layer

The insulating layer 3 is disposed between the first electrode 1 and the second electrode 2. In other words, the insulating layer 3 is disposed in contact with both the first electrode 1 and the second electrode 2. Specifically, it is preferable that no component is disposed between the insulating layer 3 and the second electrode 2. Accordingly, the surface figure of the second electrode 2 can be similar to the surface figure of the insulating layer 3. Therefore, when the thickness of the first region 31 is smaller than the thickness of the second region 32, the boundary between the first region 31 and the second region 32 is clearer. As a result, when the current supply member 41 is connected on the second electrode 2, visibility of the bonding portion can be improved. The insulating layer 3 has the first region 31 and the second region 32 thicker than the first region 31. Since the insulating layer 3 has the first region 31 having a smaller thickness than that of the second region 32, a discretionary position of dielectric breakdown can be set as the first region 31. Only one first region 31 is preferably disposed for one insulating layer 3. This can reliably set the position of the dielectric breakdown.

Part or the whole of the first region 31 is preferably surrounded by the second region 32 in a top view, and the whole of the first region 31 is preferably surrounded by the second region 32. With such a configuration, the second region 32 can reduce the influence of heat generated in the first region 31. As illustrated in FIG. 2A, the first region 31 may be provided, for example, at the center or its vicinity of the second electrode 2 in a top view. Further, in a top view, the first region 31 may be provided in the vicinity of a side of the second electrode 2 as illustrated in FIG. 2B. When the second electrode 2 is a rectangle having a long side and a short side, the first region 31 may be disposed only in a region closer to one short side than the intersection of two diagonal lines of the rectangle. In a case in which the second electrode 2 is not a strict rectangle but has a shape with chamfered corners, for example, the diagonal line can be determined with reference to a rectangle without chamfering. Such an arrangement can secure a space for the bonding region 22 of the current supply member 41, on the upper surface of the second electrode 2.

The difference in thickness between the first region 31 and the second region 32 of the insulating layer 3 can be appropriately set depending on, for example, the material of the insulating layer 3 to be used. When the insulating layer 3 is formed of SiO₂, the thickness of the first region 31 may include, for example, a range from 60% to 80% of the thickness of the second region 32. Specific examples of the thicknesses of the insulating layer 3 in the second region 32 include a range from 5 nm to 50 nm, and preferably a range from 8 nm to 20 nm. The insulating layer 3 in the second region 32 is preferably thicker than the insulating layer 3 in the first region 31 by 5 nm. Thus, specific examples of the thicknesses of the insulating layer 3 in the first region 31 include a range from 10 nm to 90 nm, and preferably a range from 13 nm to 25 nm. In at least one cross section passing through the first region 31, the thickness of the second region 32 is preferably constant, and the thickness of the second region 32 is more preferably constant over the whole region. Here, “constant” means that the thickness of the second region 32 is within a range of ±10% from a desired value. Such a configuration easily controls the breakdown voltage and/or the breakdown position of the anti-fuse element 10.

The first region 31 preferably has a circular shape in a top view but may have other shapes. The size of the first region 31 in a top view is, for example, in a range from 0.1% to 30%, and preferably in a range of 0.5% to 15% of the whole of the insulating layer 3 Specifically, the size of the first region 31 in a top view is, for example, 400 m in diameter or a size equivalent thereto or less, preferably 100 μm in diameter or a size equivalent thereto or less, and more preferably 20 μm in diameter or a size equivalent thereto or less. In addition, the size may be 10 μm in diameter or a size equivalent thereto or more, and 15 m in diameter or a size equivalent thereto or more is more preferable. Such a configuration can secure a space for the bonding region 22 of the upper surface of the second electrode 2 at which the current supply member 41 is connected. The shape of the second region 32 in a top view can be appropriately set according to the shapes of the insulating layer 3 and the first region 31. Examples of the planar shape of the insulating layer 3 include various shapes such as a circle, an ellipse, a polygon such as a triangle, a quadrangle, a hexagon, and an octagon, a shape obtained by chamfering the corners of these shapes, and a shape obtained by combining these shapes. Here, the chamfering includes C-chamfering in which a corner is obliquely cut and R-chamfering in which a corner is rounded. In particular, as a result of the corners of the quadrangle being chamfered, the shape may become an octagon in a strict sense, but such a shape may also be referred to as a quadrangle with chamfered corners. In particular, the insulating layer 3 preferably has a quadrangle with chamfered corners. Such a configuration can locally mitigate the intensity of the electric field applied to the vicinity of the vertex of the quadrangle of the insulating layer 3.

The size of the insulating layer 3 in a top view may be smaller than that of the first electrode 1 or may be the same as that of the first electrode 1. The insulating layer 3 overlaps with or is inward of the outer edge of the first electrode 1 in a top view. This can reduce the size of the anti-fuse element 10. The size of the insulating layer 3 in a top view may be larger than the second electrode 2 or the same as the second electrode 2. In particular, the size in a top view is preferably the same as that of the first electrode 1 and larger than that of the second electrode 2. In other words, preferably, the outer edge of the insulating layer 3 and the first electrode 1 coincide with each other, and the outer edge 2a of the second electrode 2 is located inward of the outer edge 3a of the insulating layer 3. Thus, part of the insulating layer 3 is preferably exposed to the outside together with the second electrode 2. Such a configuration can suppress a short circuit between the first electrode 1 and the second electrode 2. Here, the portion of the insulating layer 3 may be part of the upper surface of the insulating layer 3 on the second electrode 2 side, or may be part or the whole of the lateral surface adjacent to the upper surface. In particular, part of the upper surface and the whole lateral surface of the insulating layer 3 are more preferably exposed to the outside.

Examples of the insulating layer 3 include a layer having a single-layer structure or a multilayer structure of SiO₂, a silicon oxide film, Al₂O₃, TiO₂, Ta₂O₅, Nb₂O₅, ZrO₂, AlOₓN_{y}, SiN, and SiNₓ. Among these, SiO₂ or a silicon oxide film is preferable. Forming the insulating layer 3 using SiO₂ or a silicon oxide film having high dielectric breakdown resistance can reduce the thickness of the insulating layer 3 and achieve device size reduction and material saving.

### Second Embodiment: Light-Emitting Device

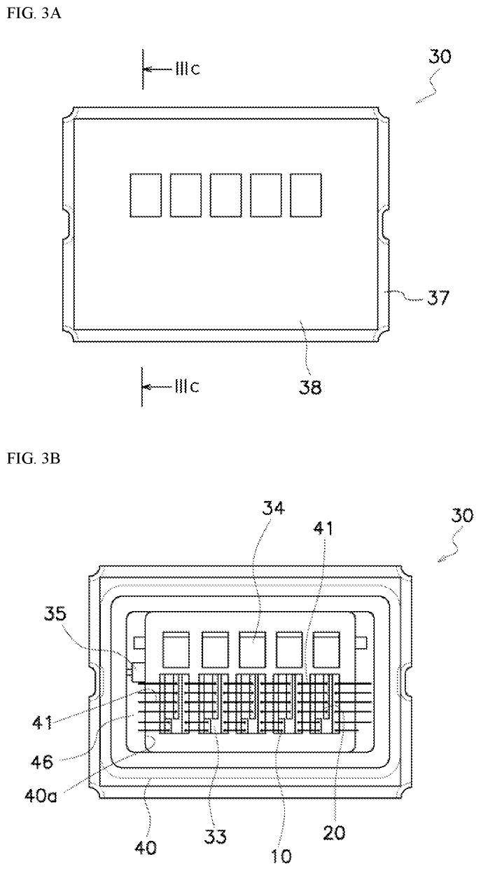

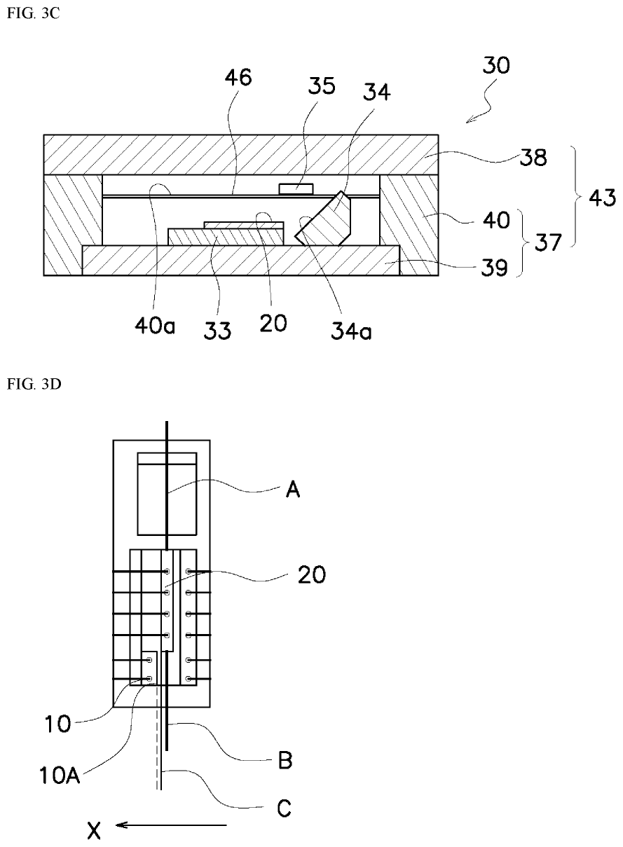

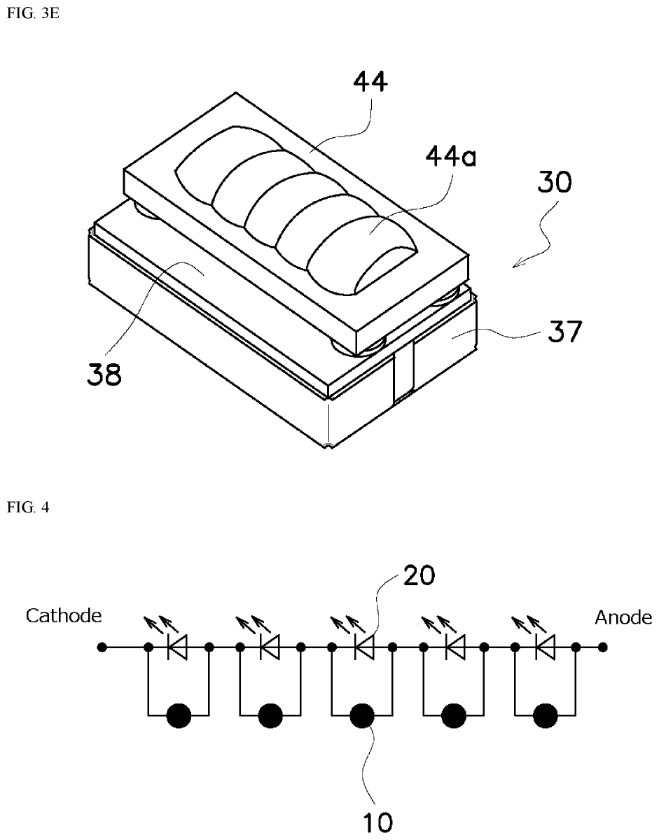

As illustrated in FIGS. 3B and 3C, a light-emitting device 30 according to the second embodiment includes an anti-fuse element 10 and a light-emitting element 20. The anti-fuse element 10 and the light-emitting element 20 are preferably disposed in a hermetically sealed closed space in a package 43 having a conductive layer 46.

In the light-emitting device 30, one anti-fuse element is preferably disposed for one light-emitting element, and when a plurality of the light-emitting elements is disposed, an anti-fuse element is disposed for each of the light-emitting elements. Such a configuration can allow conduction of the whole light-emitting device to be maintained by the action of the anti-fuse element even when any of the light-emitting elements fails to carry any current.

The light-emitting device 30 may further include the submount 33, a light reflective member 34, a protective element 35, an optical member 44, and the like.

### Light-Emitting Element

As the light-emitting element 20, a light-emitting diode, a semiconductor laser element, or the like can be used. Of these, the light-emitting element is preferably a semiconductor laser element (hereinafter, also referred to as a “semiconductor laser element 20”).

The light-emitting element, in particular, the semiconductor laser element has a rectangular outer shape in a top view. In this case, a lateral surface intersecting one of the two short sides of this rectangle serves as an emission end surface of light of the semiconductor laser element. The upper surface and the lower surface of the semiconductor laser element are larger in area than the emission end surface.

Light (laser light) emitted from the semiconductor laser element spreads and forms an elliptical far field pattern (hereinafter referred to as “FFP”) on a plane parallel to a light emission end surface. The FFP is a shape and a light intensity distribution of emitted light at a position away from the emission end surface. Here, a straight line extending through the center of the elliptical shape of the FFP is referred to as an optical axis of the semiconductor laser element, and light extending through the center of the elliptical shape of the FFP, in other words, light having a peak intensity in the light intensity distribution of the FFP is referred to as light traveling along the optical axis. In the light intensity distribution of the FFP, light having an intensity of 1/e² or more with respect to the peak intensity value is referred to as a main portion of the light. The shape of the FFP of light emitted from the semiconductor laser element is an elliptical shape such that a length in the layering direction perpendicular to the plurality of semiconductor layers including the active layer is longer than the length in the layer direction. The layer direction is referred to as the lateral direction of the FFP, and the layering direction is referred to as the vertical direction of the FFP. Based on the light intensity distribution of the FFP, an angle corresponding to a full width at half maximum of the light intensity distribution is a divergence angle of light of the semiconductor laser element. The divergence angle of the light in the vertical direction of the FFP is referred to as a vertical divergence angle, and the divergence angle of the light in the lateral direction of the FFP is referred to as a lateral divergence angle.

As the semiconductor laser element, for example, a semiconductor laser element that emits blue light, a semiconductor laser element that emits green light, a semiconductor laser element that emits red light, or a semiconductor laser element that emits light other than these can be adopted. Blue light refers to light having an emission peak wavelength in the range from 420 nm to 494 nm, green light refers to light having an emission peak wavelength in the range from 495 nm to 570 nm, and red light refers to light having an emission peak wavelength in the range from 605 nm to 750 nm.

Examples of the semiconductor laser element that emits blue light and the semiconductor laser element that emits green light include a semiconductor laser element including a nitride semiconductor. As the nitride semiconductor, for example, a semiconductor layer of GaN, InGaN, AlGaN, or the like can be used. Examples of the semiconductor laser element that emits red light include a semiconductor laser element including an InAlGaP-based, GaInP-based, or AlGaAs-based semiconductor layer. The semiconductor laser element 20 may be any of a single emitter having one emitter, a multi-emitter having two or more emitters, and the like. When the semiconductor laser element includes a plurality of the emitters, laser light that forms an elliptical FFP is emitted from the emission end surface of each emitter.

The light-emitting element, in particular, the semiconductor laser element is preferably disposed on a submount from the viewpoint of the heat dissipation property and the like.

### Submount

The submount 33 has two bonding surfaces. The submount 33 preferably has a shape of a column or a polygonal column such as a quadrangular column in which the two bonding surfaces are parallel to each other. Among these, a rectangular parallelepiped is preferable. The submount 33 can be formed using, for example, silicon nitride, aluminum nitride, or silicon carbide. A metal film for bonding is preferably provided on the bonding surface.

### Package

The package 43 is a member for providing a hermetically sealed closed space in which the anti-fuse element 10 and the light-emitting element 20 are disposed, and includes, for example, a base member 37 and a lid member 38.

The base member 37 includes the bottom portion 39 on which the anti-fuse element 10, the light-emitting element 20, and the like are disposed, and a wall portion 40 surrounding the bottom portion 39. That is, the base member 37 has a recessed portion, and the recessed portion is constituted by the bottom portion 39 and the wall portion 40.

In a top view, examples of the outer shape of the base member 37 include various shapes such as a circle, an ellipse, and a polygon such as a quadrangle, and examples of the outer shape of the recessed portion similarly include these various shapes. Among these, a rectangular shape is preferable. The bottom portion 39 preferably has a flat plate shape. The wall portion 40 extends from the outer periphery of the bottom portion to the upper side of the anti-fuse element, the light-emitting element, and the like to be higher than the height of the anti-fuse element, the light-emitting element, and the like. The wall portion 40 may extend in a flat plate shape or may have one or more steps 40a.

The bottom portion 39 and the wall portion 40 may be integrally formed of the same material, or may be formed of different materials, for example, the wall portion may be formed of ceramic and the bottom portion may be formed of metal. Examples of the ceramic include aluminum nitride, silicon nitride, aluminum oxide, and silicon carbide. As the metal, for example, Cu, Al, Fe, or the like can be used, and as the composite, copper molybdenum, a copper-diamond composite material, copper tungsten, or the like can be used. In this case, the metal used for the bottom portion 39 preferably has better heat dissipation property and higher thermal conductivity than the ceramic used for the wall portion 40.

The lid member 38 is bonded to the base member 37 under a predetermined atmosphere, and the closed space becomes a hermetically sealed space. By disposing the semiconductor laser element 20 and the like in the hermetically sealed space, it is possible to suppress quality degradation due to dust collection. For hermetic sealing, the lid member 38 is bonded to the base member 37 with, for example, a metal bonding material or the like. Examples of the metal bonding material include brazing metal such as AuSn, solder, and the like.

The lid member 38 has a lower surface and an upper surface. The lid member 38 preferably has, for example, a flat plate shape, and preferably has an outer shape corresponding to the outer shape of the base member 37 in a top view. In addition, the lid member 38 preferably has light transmissivity for transmitting light. Here, the term “light transmissivity” means that the transmittance of light emitted from the light-emitting element accommodated in the package is 50% or more, and is preferably 60% or more, 70% or more, or 80% or more. However, the lid member 38 may have a light-transmissive region only in part. The shape and the quantity of the light-transmissive regions can be appropriately selected so that light emitted from the light-emitting element 20 can be transmitted. For example, as illustrated in FIG. 3A, the quantity of light-transmissive regions may be the same as the quantity of the corresponding light-emitting elements 20. The lid member 38 is preferably provided with a metal film in a partial region on the surface thereof. The metal film is provided for bonding to another component. Thus, part or the whole of the region where the metal film is provided serves as a bonding region to be bonded to another component. In particular, preferably, the metal film is provided on a surface (hereinafter, referred to as a “lower surface”) of the lid member 38 facing the base member 37 and is provided in an annular shape along the outer edge of the lid member 38.

The lid member 38 can be formed of sapphire, glass, or the like. Sapphire is a material having light transmissivity, a relatively high refractive index, and a relatively high strength. The metal film can be formed of, for example, Ti/Pt/Au.

A wavelength conversion member may be disposed in the light-transmissive region of the lid member 38. The wavelength conversion member can contain a phosphor known in the art.

The conductive layer 46 is provided on the base member 37 of the package, in particular, on the bottom portion 39, optionally, on the upper surface of the wall portion 40, and the like, thereby electrically connecting the anti-fuse element 10, the light-emitting element 20, and the like. In FIG. 3C, the conductive layer 46 is disposed on the upper surface of the step 40a of the wall portion 40. FIG. 3C omits the member such as a wire for ease of viewing. As the shape, thickness, material, and the like of the conductive layer 46, those known in the art can be used.

A current supply member 41 connected to the anti-fuse element 10, the light-emitting element 20, and the like is connected to the conductive layer 46. A quantity of current supply member 41 connected to the anti-fuse element 10 is preferably two to four, but may be another number. Having such a quantity of current supply members 41 can realize current distribution to the plurality of current supply members 41, even when a large current flows through the anti-fuse element 10, thereby allowing the possibility of stable operation to be increased. The wiring line 41 has a string shape, for example, and is preferably a metal wire, for example. As the metal, for example, gold, aluminum, silver, copper, an alloy thereof, or the like can be used.

As illustrated in FIG. 4, the anti-fuse element 10 and the light-emitting element 20 can be connected in parallel by the conductive layer 46 and the current supply members 41 in the package 43. In addition, in a case in which such a plurality of sets of the anti-fuse element 10 and the light-emitting element 20 connected in parallel is arrayed, these sets thereof can be connected in parallel or in series, and in particular, series connection is preferable. The series connection can cause a voltage to concentrate in the corresponding anti-fuse element when one of the plurality of light-emitting elements 20 disconnects, thereby allowing a voltage sufficient for the anti-fuse element to become conductive to be secured.

In addition, in a case in which the light-emitting device includes a Zener diode as a protective element as will be described below, as illustrated in FIG. 3B, the Zener diode is preferably connected in parallel to a plurality of sets of the anti-fuse elements 10 and the light-emitting elements 20. Such a configuration can protect the whole device from the breakdown due to a reverse current.

In the light-emitting device 30 illustrated in FIG. 3B, five semiconductor laser elements 20 and five respective anti-fuse elements 10 are paired and arrayed in one direction in the package.

The arrangement of the anti-fuse elements 10 and the semiconductor laser elements 20 in the package 43 can be appropriately set according to the number and the size thereof, the shape and the size of the package, and the like. For example, as illustrated in FIG. 3D, the anti-fuse element 10 is preferably disposed in a region avoiding a virtual straight line including the optical axis A of the laser light emitted from the semiconductor laser element 20 in a top view. In other words, the anti-fuse element 10 is preferably disposed so that part or the whole of the anti-fuse element 10 does not intersect with the extension line of the optical axis A of the laser light emitted from the emission end surface. In particular, a lateral surface 10A of the anti-fuse element 10 on the side closer to the semiconductor laser element 20 is preferably located on the side away from the extension line C of the lateral surface parallel to the optical axis of the semiconductor laser element 20, that is, in the direction X away from the semiconductor laser element 20. This can suppress degradation of the anti-fuse element 10 due to leakage of light from the semiconductor laser element. The anti-fuse element 10 can be disposed on the back surface side of the semiconductor laser element 20. Here, the back surface is a surface of the semiconductor laser element 20 that is farthest from the emission end surface of the semiconductor laser element 20, and the back surface side indicates a region closer to the back surface than the emission end surface of the semiconductor laser element 20.

### Light Reflective Member

The light reflective member 34 has a light reflective surface 34a on which light is reflected. The light reflective surface 34a is inclined with respect to the lower surface and the surface of the bottom portion 39 of the package 43 on which the light reflective surface 34 is disposed. For example, the light reflective surface 34a is provided on an inclined surface having an inclination angle of in a range from 20 degrees to 80 degrees, for example, 45 degrees, with respect to the lower surface. The light reflective surface 34a may have a planar shape or a curved shape. In the case of a curved shape, a portion which is perpendicular or parallel with respect to the lower surface may be locally included. The light reflective surface 34a preferably has a planar shape.

The light reflective member 34 can be formed using glass, metal, or the like. Specific examples thereof include glass such as silica glass and BK7 (borosilicate glass), metals such as aluminum, and materials containing Si as a main material. The light reflective surface can be formed using, for example, a metal such as Ag or Al, or a dielectric multilayer film such as Ta₂O₅/SiO₂, TiO₂/SiO₂, Nb₂/SiO₂ or the like. The light reflective surface 34a has a light reflectivity of 99% or more, 95% or more, and 90% or more, for the peak wavelength of the reflected laser light.

### Optical Member 44

The optical member 44 is disposed on the lid member 38 of the package 43 in the light-emitting device 30 and is a member for performing predetermined light distribution such as light collection.

The optical member 44 has an upper surface, a lower surface, and a lateral surface, and may have a lens surface 44a. The lens surface 44a is preferably formed on either the upper surface or the lower surface. For example, the optical member 44 has a shape in which the lens surface 44a having a dome shape or the like is disposed on one surface of a flat plate shape as a whole. The lens surface 44a may be formed by one dome-shaped lens, or may have any discretionary shape in which a plurality of the lens surfaces 44a are connected to each other as illustrated in FIG. 3E, a shape in which a plurality of the lenses are arranged in parallel, and the like. The optical member 44 may be formed by integrating a plate-shaped portion and a lens, or may be formed by joining separate members. The optical member 44 may have, for example, various outer shapes in a top view, similarly to the base member 37, but preferably has a rectangular shape.

Preferably, the optical member 44 has light transmissivity, and the lens surface 44a and other portions also have light transmissivity. The optical member 44 can be formed using, for example, glass such as BK7.

### Protective Element

The protective element 35 is an element that suppresses a specific element (for example, the semiconductor laser element 20) from being broken down by an excessive current flowing therethrough. An example of the protective element is a Zener diode. The Zener diode may be formed of Si.

When the light-emitting device 30 includes the protective element 35, only one protective element 35 may be provided for the light-emitting device 30, or one protective element 35 may be provided for each of the semiconductor laser elements 20. In a case in which one protective element 35 is provided for each semiconductor laser element 20, the protective element 35 is preferably disposed in a region avoiding a virtual straight line including the optical axis A of the laser light emitted from the semiconductor laser element 20, similarly to the anti-fuse element 10. For example, the protective element 35 can be disposed on the back surface side of the semiconductor laser element 20 and on the side opposite to the anti-fuse element 10 with respect to the straight line including the optical axis A. Such an arrangement can suppress degradation of the protective element 35 due to leakage of light from the semiconductor laser element 20.

### Operation of Light-Emitting Device

In the light-emitting device 30, five semiconductor laser elements 20 are connected in series in the package 43, and the anti-fuse element 10 is connected in parallel to each of the semiconductor laser elements 20. When the light-emitting device 30 is normally driven, a current flows only through the semiconductor laser element 20, and no current flows through the anti-fuse element 10.

In a case in which the anti-fuse element 10 is not connected, when a failure occurs in any one of the semiconductor laser elements 20 and the current is interrupted, the current is interrupted in all of the other semiconductor laser elements 20 connected in series, and all of the semiconductor laser elements 20 are turned off.

On the other hand, in a case in which the anti-fuse elements 10 are connected in parallel, when a failure occurs in any of the semiconductor laser elements 20 and the current is interrupted, an excessive current is supplied to the anti-fuse element 10 connected in parallel, dielectric breakdown occurs, and the anti-fuse element 10 is brought into a conductive state. As a result, the current supply state is maintained for the other semiconductor laser element 20 in which no failure has occurred, and the semiconductor laser element 20 remains turned on.

In addition to the above embodiments, the following aspects are further disclosed.

### Aspect 1

An anti-fuse element including: a first electrode; an insulating layer disposed on the first electrode; and a second electrode disposed on the insulating layer. The insulating layer includes a first region having a small thickness and a second region having a thickness larger than the small thickness of the first region, and an outer edge of the second electrode is located inside an outer edge of the insulating layer in a top view.

### Aspect 2

The anti-fuse element according to Aspect 1, wherein the first region is surrounded by the second region in a top view.

### Aspect 3

The anti-fuse element according to Aspect 1 or 2, wherein the second electrode and part of the insulating layer are exposed to an outside.

### Aspect 4

The anti-fuse element according to any one of Aspects 1 to 3, wherein the second electrode has a quadrangular shape with chamfered corners in a top view.

### Aspect 5

The anti-fuse element according to any one of Aspect 1 to 4, wherein
in at least one cross section passing through the first region, the thickness of the second region is constant, and
a thickness of the second electrode is constant in the second region.

### Aspect 6

The anti-fuse element according to any one of Aspects 1 to 5, further including a current supply member connected to the second electrode, wherein the current supply member is disposed only above the second region.

### Aspect 7

The anti-fuse element according to any one of Aspects 1 to 6, further including a conductive substrate, wherein the first electrode is disposed on the conductive substrate, and an outer edge of the conductive substrate is located outside an outer edge of the first electrode in a top view.

### Aspect 8

The anti-fuse element according to any one of Aspects 1 to 7, wherein the conductive substrate includes, in a thickness direction, a first edge portion coinciding with the outer edge of the first electrode and a second edge portion located outside the outer edge of the first electrode.

### Aspect 9

A light-emitting device including: the anti-fuse element according to any one of Aspects 1 to 8; and a light-emitting element.

### Aspect 10

The light-emitting device according to Aspect 9, wherein the light-emitting element is a semiconductor laser element.

### Aspect 11

The light-emitting device according to Aspect 10, wherein in a top view, the anti-fuse element is disposed in a region avoiding a virtual straight line including an optical axis of laser light emitted from the semiconductor laser element.

### Aspect 12

The light-emitting device according to Aspect 10 or 11, wherein the anti-fuse element and the semiconductor laser element are connected in parallel, and a plurality of sets of the anti-fuse element and the semiconductor laser element connected in parallel is connected in series.

The light-emitting device according to the embodiments can be used for projectors, vehicle headlights, head-mounted displays, lighting, displays and the like.

What is claimed is:

1. An anti-fuse element comprising:
a first electrode;
an insulating layer disposed on the first electrode; and
a second electrode disposed on the insulating layer, wherein
the insulating layer includes a first region and a second region, with a thickness of the first region being smaller than a thickness of the second region, and
an outer edge of the second electrode is located inward of an outer edge of the insulating layer in a top view.

2. The anti-fuse element according to claim 1, wherein the first region of the insulating layer is surrounded by the second region of the insulating layer in the top view.

3. The anti-fuse element according to claim 2, wherein the second electrode and the insulating layer are partially exposed to an outside.

4. The anti-fuse element according to claim 1, wherein the second electrode has a quadrangular shape with chamfered corners in the top view.

5. The anti-fuse element according to claim 1, wherein
in at least one cross section passing through the first region, the thickness of the second region is constant, and
a thickness of the second electrode is constant above the second region.

6. The anti-fuse element according to claim 1, wherein
the second electrode is configured to be connected to a current supply member only at a portion of the second electrode above the second region of the insulating layer.

7. The anti-fuse element according to claim 1, further comprising
a conductive substrate, wherein
the first electrode is disposed on the conductive substrate, and
an outer edge of the conductive substrate is located outward of an outer edge of the first electrode in the top view.

8. The anti-fuse element according to claim 7, wherein
the conductive substrate includes, in a thickness direction, a first edge portion flush with the outer edge of the first electrode and a second edge portion located outward of the outer edge of the first electrode in the top view.

9. The anti-fuse element according to claim 8, further comprising
a back surface electrode disposed on the conductive substrate on a side opposite from the first electrode.

10. A light-emitting device comprising:
the anti-fuse element according to claim 1; and
a light-emitting element.

11. The light-emitting device according to claim 10, wherein the light-emitting element is a semiconductor laser element.

12. The light-emitting device according to claim 11, wherein in the top view, the anti-fuse element is disposed in a region avoiding a virtual straight line including an optical axis of laser light emitted from the semiconductor laser element.

13. The light-emitting device according to claim 12, further comprising
an additional anti-fuse element and an additional semiconductor laser element, wherein
the anti-fuse element and the semiconductor laser element are connected in parallel to form a first set,
the additional anti-fuse element and the additional semiconductor laser element are connected in parallel to form a second set, and
the first set and the second set are connected in series.
